(19) United States
(12) Patent Application Publication
(10) Pub. No.: US 2025/0275384 A1
(43) Pub. Date: Aug. 28, 2025

(54) DISPLAY DEVICE AND METHOD FOR MANUFACTURING THE DISPLAY DEVICE

(71) Applicant: Samsung Display Co., LTD., Yongin-si (KR)

(72) Inventors: Seung Wook KWON, Yongin-si (KR); HEECHANG YOON, Yongin-si (KR); Jeong Seok LEE, Yongin-si (KR); Hee Jun YANG, Yongin-si (KR); Soomin Oh, Yongin-si (KR)

(21) Appl. No.: 18/929,276

(22) Filed: Oct. 28, 2024

(30) Foreign Application Priority Data
Feb. 28, 2024 (KR) 10-2024-0028791

(51) Int. Cl. H10K 59/126; H10K 59/12; H10K 102/00

(52) U.S. Cl. CPC H10K 59/126; H10K 59/1201; H10K 2102/311; H10K 2102/351

(57) ABSTRACT

A display device includes a display panel having different first and second areas on one surface, and a coating layer on the one surface of the display panel, the coating layer including a light blocking cushion portion in the first area, and a first support portion in the second area located on one side of the first area to support the display panel.

### CROSS-REFERENCE TO RELATED APPLICATION

This application claims priority to and the benefit of Korean Patent Application No. 10-2024-0028791 filed at the Korean Intellectual Property Office on Feb. 28, 2024, the entire content of which is incorporated herein by reference.

### BACKGROUND

### 1. Field

Aspects of the present disclosure relates to a display device and a method of manufacturing the display device.

### 2. Description of the Related Art

The importance of display devices is increasing with the development of multimedia.

Such display devices include liquid crystal displays (LCD) and organic light emitting displays (OLED).

An organic light emitting display device includes a display panel including an organic light emitting element.

In an organic light emitting device, a cathode electrode and an anode electrode are arranged around an organic light emitting layer, and when a voltage is applied to these two electrodes, visible light is generated from the organic light emitting layer connected to both electrodes.

Organic light emitting display devices are widely used in portable electronic devices such as smartphones, and are therefore often exposed to external shocks.

Additionally, if excessive heat is generated from the organic light emitting device or the driver chip that drives it, there is a risk that the device may be damaged.

In order to protect the display device from such hazards, a cover panel having functions such as light blocking, shock resistance, support, and heat dissipation is provided on the bottom of the display panel.

This cover panel may be manufactured in the form of a film and attached to the display panel.

However, dead space may occur due to the tolerances of the film itself and the lamination process, and if the structure or shape of the display panel is changed, the existing film is difficult to use and must be discarded.

The above information disclosed in this Background section is only for enhancement of understanding of the background of the invention and therefore it may contain information that does not form the prior art.

### SUMMARY

Aspects of embodiments of the present disclosure are directed to a display device and a method of manufacturing the display device that can reduce material costs, efficiently secure the desired characteristics for each position of the display panel, and easily control the thickness, size, shape, and/or the like of the coating layer.

The problems of the present disclosure are not limited to the problems mentioned above, and other technical problems not mentioned will be clearly understood by those skilled in the art from the description below.

According to some embodiments of the present disclosure, there is provided a display device including: a display panel having different first and second areas on one surface; and a coating layer on the one surface of the display panel, the coating layer including a light blocking cushion portion in the first area, and a first support portion in the second area located on one side of the first area to support the display panel.

In some embodiments, the light blocking cushion portion has a different thickness from the first support portion.

In some embodiments, the coating layer further includes a second support portion on the light blocking cushion portion.

In some embodiments, the coating layer has a shape where the thickness gradually decreases from one end to the outside.

In some embodiments, in a plane parallel to the one surface of the display panel, the coating layer has a round shape at one corner area.

In some embodiments, the light blocking cushion portion includes a first material mixed with an elastic material that includes at least one of silicon, urethane, epoxy acrylate, or polyethylene, and a light blocking material including at least one of graphene oxide (GO), reduced graphene oxide (RGO), aluminum, carbon black (CB), or copper (Cu).

In some embodiments, the first support portion includes a second material including at least one of silicon, urethane, epoxy acrylate, or polyethylene.

In some embodiments, the display panel includes a bending area adjacent to the first area on the one surface.

In some embodiments, the first area is located on one side of the bending area in a first direction, and the second area is located on an other side of the bending area in the first direction.

In some embodiments, the display panel includes a substrate exposed on the one surface and including glass.

In some embodiments, the substrate includes: a through portion in which the bending area is etched, a first substrate on one side of the through portion in a first direction, and a second substrate located on an other side of the through portion in the first direction.

In some embodiments, the display panel includes a substrate exposed on the one surface and including polyimide.

According to some embodiments of the present disclosure, there is provided a display device including: a display panel; and a coating layer on one side of the display panel, the coating layer including a light blocking cushion portion on the one side of the display panel, and a support portion on the light blocking cushion portion to support the display panel.

In some embodiments, the light blocking cushion portion includes a first material mixed with an elastic material that includes at least one of silicon, urethane, epoxy acrylate, or polyethylene, and a light blocking material including at least one of graphene oxide (GO), reduced graphene oxide (RGO), aluminum, carbon black (CB), or copper (Cu).

In some embodiments, the support portion includes a second material including at least one of silicon, urethane, epoxy acrylate, or polyethylene.

According to some embodiments of the present disclosure, there is provided a method of manufacturing a display device, the method including: providing a substrate having different first and second regions on one surface; forming a light emitting layer on an other side of the substrate and forming a thin film encapsulation layer on the light emitting layer; forming a light blocking cushion in a first area of the substrate through an inkjet printing process, and forming a first support portion in a second area of the substrate through the inkjet printing process to form a coating layer.

In some embodiments, the forming of the light blocking cushion portion includes: the forming of the light blocking cushion portion to have a different thickness from the first support portion.

In some embodiments, the forming of the coating layer further includes: forming of a second support portion on the light blocking cushion portion.

In some embodiments, the forming the coating layer includes: forming the light blocking cushion portion using a first material mixed with an elastic material including at least one of silicon, urethane, epoxy acrylate, or polyethylene, and a light blocking material including at least one of graphene oxide (GO), reduced graphene oxide (RGO), aluminum, forming carbon black (CB), or copper (Cu); and forming of the first support portion using a second material including at least one of silicon, urethane, epoxy acrylate, or polyethylene.

According to some embodiments of the present disclosure, there is provided a method of manufacturing a display device, the method including: providing a substrate having different first and second regions on one surface; forming a light emitting layer on an other side of the substrate and forming a thin film encapsulation layer on the light emitting layer; forming a light blocking cushion portion in the first region and the second region of the substrate by an inkjet printing process; and forming a support portion on the light blocking cushion portion by the inkjet printing process to include a different material from the light blocking cushion portion to form a coating layer.

According to some embodiments, material costs of the display device can be reduced, desired characteristics for each position of the display panel can be efficiently secured, and the thickness, size, shape, etc. of the coating layer can be easily controlled.

Other aspects, features, and characteristics that are not described above will be more clearly understood from the accompanying drawings, claims, and detailed description.

### BRIEF DESCRIPTION OF THE DRAWINGS

Non-limiting and non-exhaustive embodiments according to the present disclosure are described with reference to the following figures, wherein like reference numerals refer to like parts throughout the various views unless otherwise specified.

FIG. 1 is a perspective view illustrating a display device according to some embodiments of the present disclosure.

FIG. 2 is a cross-sectional view of the display device taken along the line II-II′ of FIG. 1, according to some embodiments of the present disclosure.

FIG. 3 is a plan view of a display device according to some embodiments of the present disclosure.

FIG. 4 is a plan view showing a coating layer according to some embodiments of the present disclosure.

FIG. 5 is a cross-sectional view showing a coating layer according to some embodiments of the present disclosure.

FIGS. 6 and 7 are diagrams showing a portion of the back of the display device according to some embodiments of the present disclosure.

FIG. 8 is a cross-sectional view of the display device taken along the line II-II′ of FIG. 1 according to some other embodiments of the present disclosure.

FIG. 9 is a plan view of a display device according to some other embodiments of the present disclosure.

FIG. 10 is a cross-sectional view of a display device taken along the line II-II′ of FIG. 1, according to some other embodiments of the present disclosure.

FIG. 11 is a plan view of a display device according to some other embodiments of the present disclosure.

FIG. 12 is a cross-sectional view of the display device taken along the line II-II′ of FIG. 1 according to some other embodiments of the present disclosure.

FIG. 13 is a plan view of a display device according to some other embodiments of the present disclosure.

FIG. 14 is a cross-sectional view of a display device according to a modified example.

FIG. 15 is a cross-sectional view of the display device along the line II-II′ of FIG. 1, according to some other embodiments of the present disclosure.

FIG. 16 is a plan view of a display device according to some other embodiments of the present disclosure.

FIG. 17 is a cross-sectional view of the display device taken along line II-II′ of FIG. 1 according to some other embodiments of the present disclosure.

FIG. 18 is a plan view of a display device according to some other embodiments of the present disclosure.

FIG. 19 is a flowchart showing a method of manufacturing a display device according to some embodiments of the present disclosure.

FIG. 20 is a cross-sectional view showing process S130 of FIG. 19, according to some embodiments of the present disclosure.

FIG. 21 is a cross-sectional view showing process S140 of FIG. 19, according to some embodiments of the present disclosure.

FIG. 22 is a flowchart showing a method of manufacturing a display device according to some other embodiments of the present disclosure.

FIGS. 23 and 24 are cross-sectional views showing process S230 of FIG. 22, according to some other embodiments of the present disclosure.

### DETAILED DESCRIPTION

The aspects and features of the present disclosure and methods for achieving them will become clear by referring to the embodiments described in detail below along with the accompanying drawings. However, the present disclosure is not limited to the embodiments disclosed below and will be implemented in various different forms, the present embodiments only serve to ensure that the disclosure of the present disclosure is complete and that common knowledge in the technical field to which the present disclosure pertains is not limited, while it is provided to fully inform those who have the scope of the invention, and the present disclosure is only defined by the scope of the claims.

A person of ordinary skill in the art would appreciate, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the present disclosure, processes, elements, and techniques that are not considered necessary for those having ordinary skill in the art to have a complete understanding of the aspects and features of the present disclosure may not be described or may be only briefly described. In the drawings, the relative sizes of elements, layers, and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art. Further, if the term “substantially” is used in combination with a feature that could be expressed using a numeric value, the term “substantially” denotes a range of +/−5% of the value centered on the value.

Furthermore, a specific quantity or range recited in this written description or the claims may also encompass the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

Hereinafter, specific embodiments will be described with reference to the attached drawings.

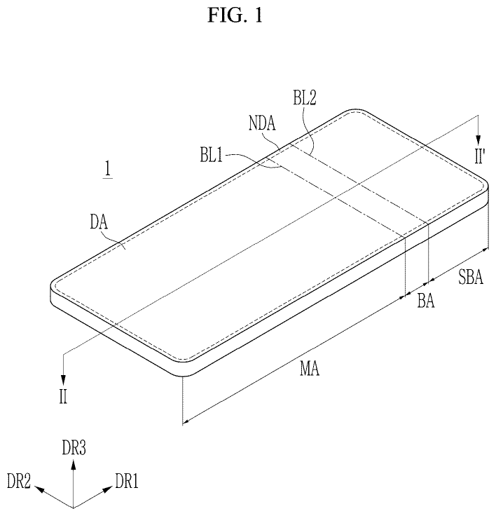

FIG. 1 is a perspective view illustrating a display device according to some embodiments of the present disclosure.

FIG. 1 shows the display device 1 unfolded without being bent at the folding lines.

Referring to FIG. 1, a display device 1 according to some embodiments is a device that displays moving images or still images, and is used in mobile phones, smart phones, tablet PCs, smart watches, watch phones, mobile communication terminals, electronic notebooks, and electronic devices, and it can be used as a display screen for various products such as televisions, laptops, monitors, billboards, and the Internet of Things, as well as portable electronic devices such as books, portable media players (PMPs), navigation, and ultra-mobile personal computers (UMPCs). The display device 1 has a three-dimensional shape.

In the drawing, the direction parallel to the first side (e.g., horizontal side) of the display device 1 is referred to as the first direction DR1, and the direction parallel to the second side (e.g., vertical side) of the display panel PNL is referred to as the second direction DR2, while the thickness direction of the display device 1 is indicated as the third direction DR3. In the following specification, unless otherwise specified, “direction” may refer to both directions extending along that direction. In addition, if it is necessary to distinguish between the two “directions” extending to both sides, one side will be referred to as “one side direction” and the other side will be referred to as “other side direction”. Based on FIG. 1, the direction the arrow points is referred to as one side, and the opposite direction is referred to as the other side. The first to third directions DR1 to DR3 may be perpendicular to each other, but are not limited thereto.

As shown in FIG. 1, the planar shape of the display device 1 has a rectangular shape such that the horizontal side is shorter than the vertical side, and each corner of the display device 1 has a right-angled planar shape or a rounded planar shape, but is not limited to this.

The display panel PNL includes a main area MA, a bending area BA, and a sub-area SBA.

The main area MA is a portion of the display panel PNL and may be disposed on one side of the second direction DR2. The sub-area SBA is a portion of the display panel PNL and may be disposed on the other side of the second direction DR2. The sub-area SBA may be an area extending from one side of the bending area BA. The sub-area SBA may include a display driver and a pad portion connected to the circuit board.

The sub-area SBA may include a flexible material capable of bending, folding, rolling, etc. For example, when the sub-area SBA is bent, the sub-area SBA may overlap the main area MA in the thickness direction (e.g., the third direction DR3). The bending area BA may be a bendable area. The bending area BA may be placed between the main area MA and the sub-area SBA. That is, the main area MA may be placed on one side of the bending area BA in the second direction DR2, and the sub-area SBA may be placed on the other side of the bending area BA in the second direction DR2.

The bending area BA may be an area defined by the first bending line BL1 and the second bending line BL2. The first bending line BL1 and the second bending line BL2 may be lines that guide the bending position of the bending area BA. The first bending line BL1 may be a boundary between the main area MA and the bending area BA, and the second bending line BL2 may be a boundary between the sub-area SBA and the bending area BA. The first bending line BL1 and the second bending line BL2 may extend in the first direction DR1, but are not limited thereto.

When the bending area BA is not bent, the display device 1 maintains the unfolded state (hereinafter referred to as “first state”) as shown in FIG. 1, and when the bending area BA is bent, the display device 1 may maintain the folded state (hereinafter referred to as the “second state”).

The display device 1 may be converted from the first state to the second state by being folded in the second direction DR2 by the first bending line BL1 and the second bending line BL2. Because of this, the length of the display device 1 in the second direction DR2 may be reduced, making it convenient for the user to carry the display device 1.

The display device 1 includes a display area DA and a non-display area NDA.

The display area DA may be an area where pixels are arranged to display an image. The non-display area NDA may be an area that does not and is not capable of displaying an image. In the first state of the display device 1, one side of the display device 1 in the third direction DR3 is the front where the display area DA and the non-display area NDA are arranged, and the other side of the display device 1 in the third direction DR3 of the surface may be the back of the display device 1. A coating layer 100, which will be described later, may be located on the other side of the display device 1. As shown in FIG. 1 in the first state of the display device 1, the display area DA is disposed on one side of the display device 1 in the third direction DR3 and includes the main area MA and the bending area BA may overlap with the sub-area SBA in the third direction DR3. That is, in the first state of the display device 1, one side of the main area MA, the bending area BA, and the sub-area SBA in the third direction DR3 is the front surface where the display area DA is disposed, and the other surface in the third direction DR3 may be a rear surface on which the display area DA is not disposed. The planar shape of the display area DA may follow the planar shape of the display device 1 in the first state. For example, when the planar shape of the display device 1 in the first state is rectangular, the planar shape of the display area DA may also be rectangular.

The non-display area NDA may be arranged around the display area DA. The non-display area NDA may be arranged to surround the display area DA, but is not limited thereto. For example, the display area DA may be partially surrounded by the non-display area NDA.

For example, the display device 1 may be folded using an out-folding method so that the back surfaces face each other, but the display device 1 is not limited thereto. For example, the display device 1 can be folded in a folding method where a portion of the display area DA overlapping with the main area MA and a portion of the display area DA overlapping with the sub-area SBA face each other.

Display pads may be disposed in the non-display area NDA to be connected to circuit boards. The display pads may be disposed at one edge of the display panel PNL. For example, the display pads may be disposed at the lower edge of the display panel PNL.

Driver integrated circuits (ICs) may be disposed between the display pads and the display area DA in the non-display area NDA. Each of the driver ICs may be attached to the non-display area NDA of the display panel PNL using a chip on glass COG method. In some examples, each of the drivers ICs may be attached to a circuit board using a COP (chip on plastic) method.

Driver ICs may generate data voltages, power voltages, scan timing signals, etc. Driver ICs may output data voltages, power voltages, scan timing signals, etc. Circuit boards may be disposed on display pads disposed at one edge of the display panel PNL. Circuit boards may be attached to the display pads using a conductive adhesive member such as an anisotropic conductive film and an anisotropic conductive adhesive. Because of this, the circuit boards can be electrically connected to signal wires of the display panel PNL. The circuit boards may be flexible printed circuit boards or flexible films such as chip on films.

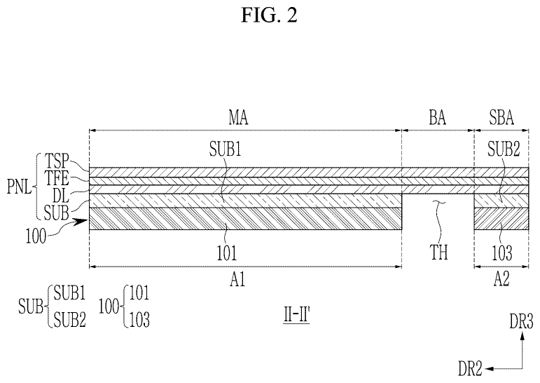

Below, with reference to FIGS. 2 to 7, a coating layer according to some embodiments will be described.

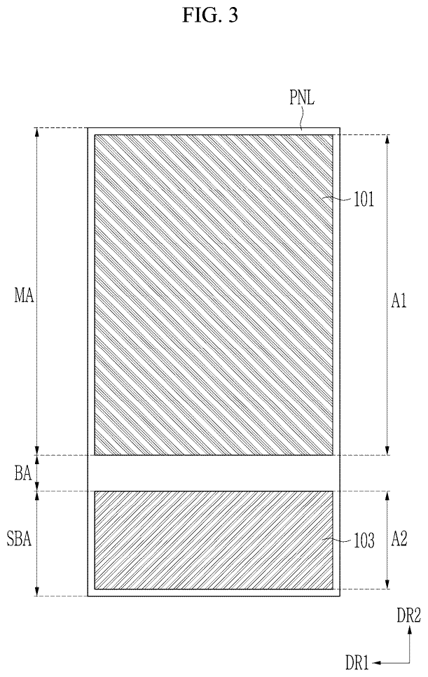

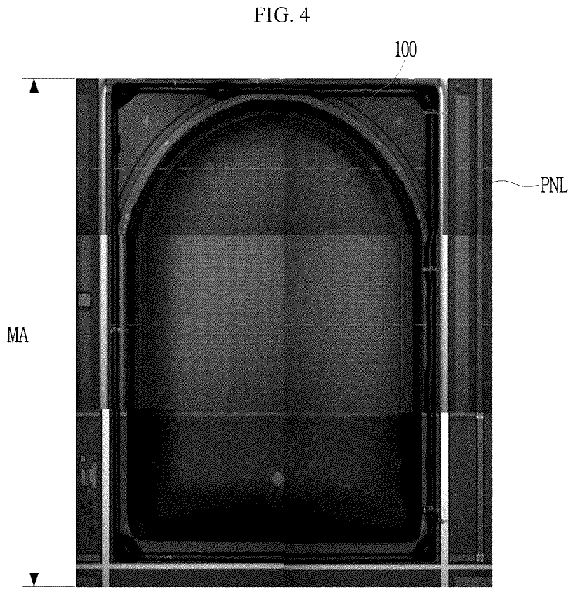

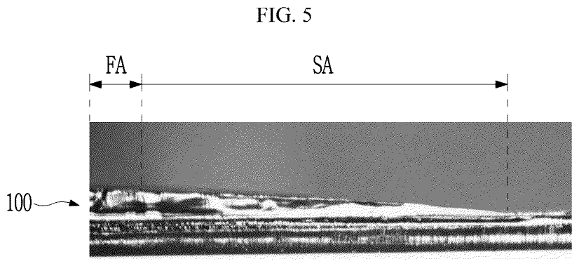

FIG. 2 is a cross-sectional view of the display device taken along the line II-II′ of FIG. 1, according to some embodiments of the present disclosure; FIG. 3 is a plan view of the display device according to some embodiments of the present disclosure; FIG. 4 is a plan view showing a coating layer according to some embodiments of the present disclosure; and FIG. 5 is a cross-sectional view showing a coating layer according to some embodiments of the present disclosure. FIG. 3 is a plan view showing the rear of the display device 1 viewed from the other side along the third direction DR3. FIG. 4 is a plan view showing the rear main area of the display device 1 as seen from the other side along the third direction DR3.

Referring to FIGS. 2 and 3, the display panel PNL may include a substrate SUB, a display layer DL, a thin film encapsulation layer TFE, and a touch electrode layer TSP in the stacking order.

The substrate SUB may serve to support several layers included in the display panel PNL at the base of the display panel PNL.

The substrate SUB may be made of a hard material. For example, the substrate SUB may be made of glass. The substrate SUB may be made of ultra thin glass UTG with a thickness of about 500 μm or less.

The substrate SUB may have a through portion TH in which the bending area BA is etched. The substrate SUB may include a first substrate SUB1 located on one side according to the first direction DR1 of the through hole TH, and a second substrate SUB2 located on the other side according to the first direction of the through hole TH.

The substrate SUB may have one surface on which the coating layer 100 is disposed, and the other surface on which the display layer DL is disposed, which faces the one surface in the third direction DR3. The display layer DL may be a layer that displays an image. The display layer DL may include a thin film transistor layer in which thin film transistors are formed and a light emitting device layer in which light emitting devices that emit light are disposed in light emitting areas.

In the display area DA of the display layer DL, scan wires, data wires, power wires, etc. for the light emitting areas to emit light may be disposed. A scan driving circuit unit that outputs scan signals to scan wires and fan-out wires that connect data wires and a driver IC may be disposed in the non-display area NDA of the display layer DL.

The thin film encapsulation layer TFE may serve to prevent or substantially impede external moisture and oxygen from penetrating into the light emitting device layer of the display layer DL. The thin film encapsulation layer TFE may be disposed on the display layer DL. The thin film encapsulation layer TFE may be disposed on the top and side surfaces of the display layer DL. The thin film encapsulation layer TFE may be disposed to cover the display layer DL.

The thin film encapsulation layer TFE may include at least one organic layer and one or more inorganic layers. One organic layer and one or more inorganic layers may be stacked alternating with each other.

The touch electrode layer TSP may play a role in recognizing the user's hand movements. For example, the touch electrode layer TSP can recognize the user's hand movements using a self-capacitance method or a mutual capacitance method. The touch electrode layer TSP is disposed on the thin film encapsulation layer TFE and may be disposed in the display area DA and the non-display area NDA.

The touch electrode layer TSP may include a touch protection layer, at least one conductive layer, and an insulating layer. One or more conductive layers and one or more insulating layers may be stacked on one another. The touch protection layer may be an organic layer. For example, the touch protection layer may include at least one of acrylic resin, siloxane resin, or polyimide resin.

The planar shape of the touch electrode layer TSP may be the same as the planar shape of the thin film encapsulation layer TFE. That is, the touch electrode layer TSP and the thin film encapsulation layer TFE may completely overlap in the third direction DR3. Meanwhile, the touch electrode layer TSP may be omitted depending on the platform of the display device 1.

In addition, a polarizing member may be disposed on the display panel PNL. The polarizing member may serve to improve display quality by polarizing light incident from the outside into the display area DA of the display panel PNL. The polarizing member may be disposed on the touch electrode layer TSP (on the thin film encapsulation layer TFE if the touch electrode layer TSP is omitted). The polarizing member may be disposed in the display area DA and the non-display area NDA and may have a planar shape substantially the same as that of the main area MA of the display panel PNL, but is not limited thereto. For example, the polarizing member may be disposed only in the display area DA and not in the non-display area NDA.

Additionally, a window cover may be placed on the polarizing member. The window cover may serve to protect elements inside the display panel PNL from the outside. Window covers may be made of glass, sapphire, plastic, and/or the like. The window cover may be a transparent adhesive film containing an ultraviolet curing material that transmits visible light. A coating layer 100 may be disposed on the back of the display panel PNL. For example, because the substrate SUB is located at the bottom of the display panel PNL in the third direction DR3, the coating layer 100 may be located on the back of the substrate SUB. The display panel PNL may have a different first area A1 and a second area A2 on the rear surface. For example, because the substrate SUB is located at the bottom of the display panel in the third direction DR3, different first areas A1 and second areas A2 are formed on the back of the substrate SUB. The substrate SUB may be exposed from the back of the display panel PNL.

The coating layer 100 may cover at least a portion of the rear surface of the display panel PNL. The coating layer 100 may be disposed to expose at least a portion of the display panel PNL.

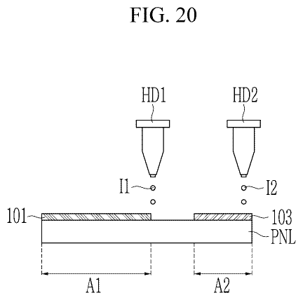

In some embodiments, the coating layer 100 may be formed by an inkjet printing process. For example, the coating layer 100 may be formed by applying an inkjet head (see, e.g., FIG. 20, HD1/2) on the display panel PNL and curing it. The coating layer 100 may be cured through at least one of ultraviolet curing, thermal curing, or natural curing. The coating layer 100 may be cured in-situ or post-cured.

The coating layer 100 may include a light blocking cushion portion 101 and a first support portion 103. The light blocking cushion portion 101 may be disposed in the first area A1. The first support portion 103 may be disposed in the second area A2. The light blocking cushion portion 101 and the first support portion 103 may include different materials.

The light blocking cushion portion 101 may be arranged to block at least a portion of the light incident on the display panel PNL. The first support portion 103 may be disposed in the second area A2 to support the display panel PNL. The second area A2 may be located on one side of the first area A1.

The first area A1 may be located on one side of the bending area BA along the second direction DR2. The second area A2 may be located on the other side of the bending area BA in the second direction DR2. Accordingly, the light blocking cushion portion 101 and the first support portion 103 may be arranged to face each other in the first direction DR1. The bending area BA may be disposed adjacent to the first area A1. The bending area BA may be disposed adjacent to the second area A2.

The bending area BA may be located between the first area A1 and the second area A2 along the first direction DR1.

In FIGS. 2 and 3, the first area A1 is shown as having a similar size to the main area MA, but this is merely an example, and the first area A1 is the light blocking cushion portion in the main area MA, and the area where the light blocking cushion portion 101 is placed may be smaller or larger than the main area MA depending on the purpose and use of the display device 1.

Also, in FIGS. 2 and 3, the first area A1 is shown as being singular, but this is only an example, and the first area A1 is an area where the light blocking cushion portion 101 is placed in the main area MA, and depending on the purpose and use of the display device 1, it can be provided in any position within the rear sub-area SBA of the display panel PNL in singular or plural form.

In FIGS. 2 and 3, the second area A2 is shown as having a similar size to the sub-area SBA, however, this is merely an example, and the second area A2 is connected to the first support in the sub-area SBA, and the area where the first support 103 is placed may be smaller or larger than the sub-area SBA depending on the purpose and use of the display device 1. In addition, in FIGS. 2 and 3, the second area A2 is shown in singular form, but this is merely an example, and the second area A2 is an area where the first support 103 is placed in the sub-area SBA, and depending on the purpose and use of the display device 1, it can be provided in singular or in plural form in any area of the sub-area SBA on the back of the display panel PNL.

The perimeter of the coating layer 100 may be disposed adjacent to the perimeter of the display panel PNL. The perimeter of the coating layer 100 may be located inside the perimeter of the display panel PNL, but is not limited thereto. The circumferential shape of the coating layer 100 may correspond to the circumferential shape of the display panel PNL. For example, referring to FIG. 4, in a plane parallel to one surface of the display panel PNL, the coating layer 100 may have a round shape at one corner area. In other words, in a plane perpendicular to the third direction DR3 (i.e., in a plan view), the light blocking cushion portion 101 may have a round shape at one corner area. Additionally, in a plane perpendicular to the third direction DR3 (i.e., in a plan view), the first support portion 103 may have a round shape at one corner area.

Referring to FIG. 5, the coating layer 100 may include a flat portion FA and an inclined portion SA.

The flat portion FA may occupy most of the area of the coating layer 100. The top surface of the coating layer 100 in the flat portion FA may be flat. The thickness of the coating layer 100 in the flat portion FA may be substantially constant. Here, constant thickness may mean that the difference in thickness of the coating layer 100 is within about ±6% of the average thickness.

The slope SA may be disposed around the display panel PNL and adjacent to the through portion TH of the substrate SUB. The slope SA may be formed at an edge area of the coating layer 100. The upper surface of the inclined portion SA may be an inclined surface. The inclined surface may be curved in a cross-sectional view, but is not limited thereto, and may also be straight in some examples.

The thickness of the inclined portion SA of the coating layer 100 may become smaller as it approaches the circumference of the display panel PNL, and may become smaller as it approaches the through portion TH of the substrate SUB. The thickness of the inclined portion SA may be thicker as it approaches the flat portion FA. The coating layer 100 may have a shape whose thickness gradually decreases from one end to the outside. In a cross-section perpendicular to one side of the display panel PNL, the coating layer 100 may have a shape whose thickness along the third direction DR3 gradually decreases as it moves outward along the second direction DR2.

Specifically, referring to FIGS. 2 and 3 together, the light blocking cushion portion 101 may have a shape whose thickness gradually decreases from one end to the outside. In a cross-section perpendicular to one side of the display panel PNL, the light blocking cushion portion 101 may have a shape whose thickness along the third direction DR3 gradually decreases as it moves outward along the second direction DR2. As an example, the thickness of the light blocking cushion portion 101 may be 10 μm to 130 μm.

Additionally, the first support portion 103 may have a shape whose thickness gradually decreases from one end to the outside. In a cross-section perpendicular to one side of the display panel PNL, the first support portion 103 may have a shape whose thickness along the third direction DR3 gradually decreases as it moves outward along the second direction DR2. For example, the thickness of the first support portion 103 may be 10 μm to 150 μm.

In some embodiments, the light blocking cushion portion 101 is made of a first material mixed with an elastic material and a light blocking material. The elastic material may include at least one of silicon, urethane, epoxy acrylate, and polyethylene. The light blocking material may include at least one of graphene oxide GO, reduced graphene oxide RGO, aluminum, carbon black CB, and copper Cu. The light blocking material may be a material with an optical density OD of 3.0 or more. The first material may include low viscosity acrylate. The first material may include a nanocomposite in the range of 3% to 50%. For example, the light blocking cushion portion 101 may be formed by curing an ink containing the first material, but is not limited thereto. The light blocking cushion portion 101 may be cured in air (O₂) or cured in nitrogen N₂.

In some embodiments, the first support portion 103 may include a second material including at least one of silicon, urethane, epoxy acrylate, or polyethylene. The second material may be a high modulus material. The modulus of the second material may be from several to hundreds of Mpa. The second material may be a low viscosity material of 30 cPs or less. For example, the first support portion 103 may be formed by curing ink containing the second material, but is not limited thereto. The first support 103 may be curable in air O₂ or nitrogen N₂.

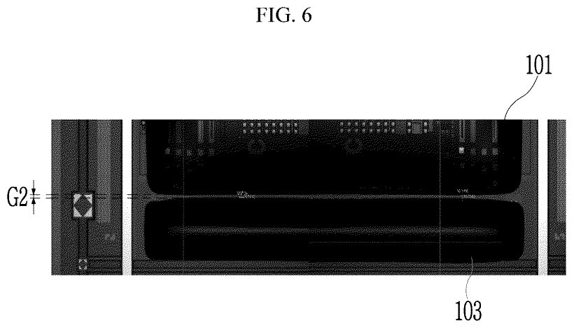

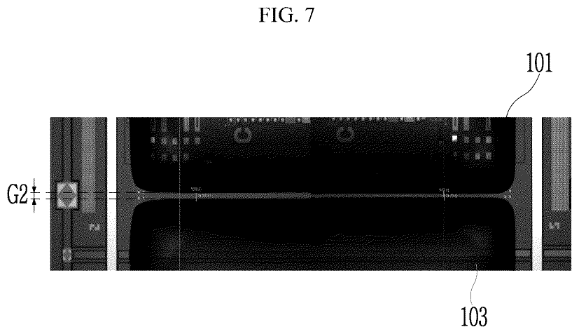

FIG. 6 and FIG. 7 are diagrams showing a portion of the back of the display device according to some embodiments of the present disclosure. Referring to FIG. 6, the first distance G1 may be a distance along the second direction DR2 between the light blocking cushion portion 101 and the first support 103 according to some embodiments. Referring to FIG. 7, the second distance G2 may be a distance in the second direction DR2 between the light blocking cushion portion 101 and the first support 103 according to a modified example. The first distance G1 and the second distance G2 may be different. In the display device according to such embodiments, a coating layer can be easily formed through inkjet printing at a desired location according to design changes, etc., and thus the distance between the light blocking cushion portion and the support portion can also be easily changed.

In the past, separate films that functioned for light blocking, impact resistance, and support were manufactured to correspond to the shape of the display panel and attached through a lamination process. In this case, the existing film had to be discarded when the design was changed, resulting in a loss, and this problem occurs and dead space occurs due to tolerances that occur during the film attachment process.

In the display device according to the above-described embodiments, the above-described problems are solved by forming a coating layer that functions for light blocking, impact-resistance, and supporting using materials with different physical properties according to the desired characteristics for each position of the display panel through inkjet printing. This reduces material costs, secures the desired characteristics for each position of the display panel, and forms a coating layer within ±50 μm based on the edge of the bending area.

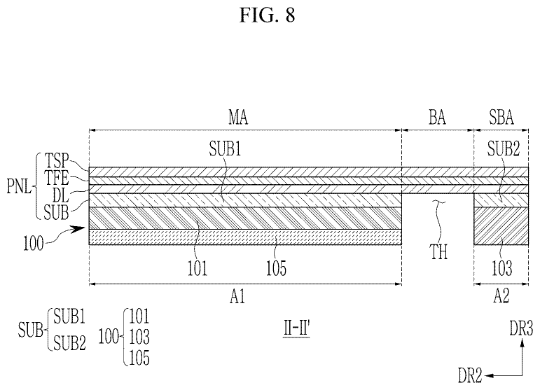

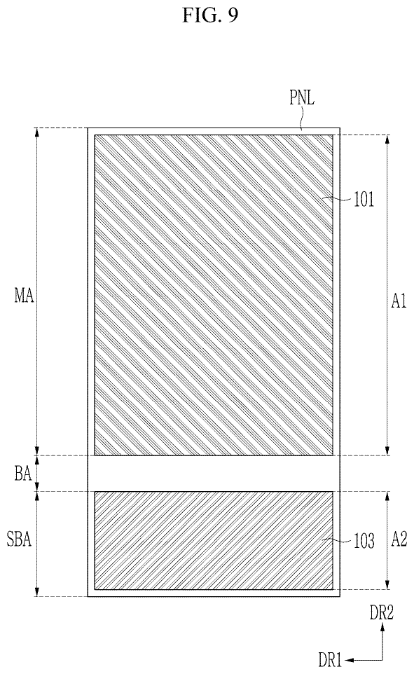

FIG. 8 is a cross-sectional view of a display device taken along the line II-II′ of FIG. 1 according to some embodiments of the present disclosure; and FIG. 9 is a top view of the display device according to some other embodiments of the present disclosure. FIG. 9 is a plan view showing the rear of the display device 1 viewed from the other side along the third direction DR3.

The display device according to the embodiments of FIGS. 8 and 9 is different from the embodiments of FIGS. 1 to 7 only in the shape and configuration of the coating layer 100. Accordingly, in FIGS. 8 and 9, descriptions overlapping with the embodiments of FIGS. 1 to 7 may not be repeated.

Referring to FIGS. 8 and 9, the coating layer 100 may include the light blocking cushion portion 101, a first support portion 103, and a second support portion 105. The light blocking cushion portion 101 may be disposed in the first area A1. The first support portion 103 may be disposed in the second area A2. The second support portion 105 may be disposed in at least a portion of the first area A1. The second support portion 105 may be disposed on the light blocking cushion portion 101. The second support portion 105 may be arranged to support the display panel PNL. The light blocking cushion portion 101 and the first and second support portions 103 and 105 may include different materials. As an example, the above different materials may mean materials with different characteristics such as transmittance, haze, modulus, or elongation.

The light blocking cushion portion 101 according to some other embodiments may have a different thickness from the first support portion 103. With respect to the thickness along the third direction DR3, the thickness of the light blocking cushion portion 101 and the first support portion 103 may be different. The thickness of the first support portion 103 may be greater than the thickness of the light blocking cushion portion 101.

In a plane perpendicular to the third direction DR3, the second support portion 105 may have a round shape at one corner area. The second support portion 105 may have a shape whose thickness gradually decreases from one end to the outside. In a cross-section perpendicular to one side of the display panel PNL, the second support portion 105 may have a shape whose thickness along the third direction DR3 gradually decreases as it moves outward along the second direction DR2. For example, the thickness of the second support portion 105 may be about 10 μm to about 150 μm.

In some embodiments, the second support portion 105 may include a second material including at least one of silicon, urethane, epoxy acrylate, and polyethylene. The second material may be a high modulus material. The modulus of the second material may be from several to hundreds of Mpa. The second material may be a low viscosity material of 30 cPs or less. For example, the second support portion 105 may be formed by curing ink containing the second material, but is not limited thereto. The second support portion 105 may include the same or substantially the same material as the first support portion 103, but is not limited thereto.

The second support portion 105 may be curable in air O₂ or nitrogen N₂.

In the display device according to some other embodiments described above, the light blocking cushion portion, the first support portion, or the second support portion can be formed at a desired location with a desired shape and thickness depending on the level of functional requirements such as shock resistance, light blocking, and support, so that the display can be formed, and the desired characteristics for each location of the panel can be efficiently secured.

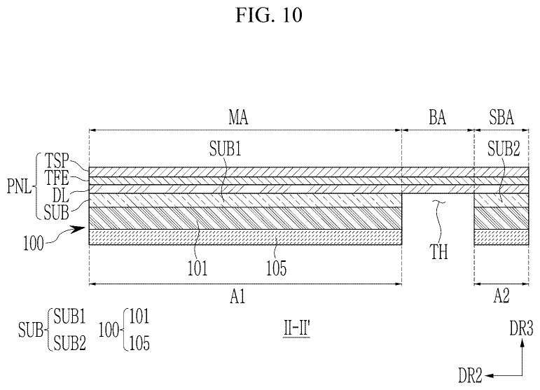

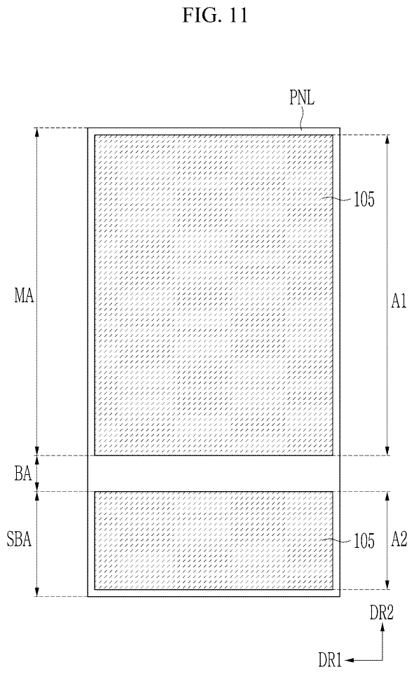

FIG. 10 is a cross-sectional view of a display device according to some other embodiments taken along the line II-II′ of FIG. 1, according to some other embodiments of the present disclosure; and FIG. 11 is a top view of the display device according to some other embodiments of the present disclosure. FIG. 11 is a plan view showing the rear of the display device 1 viewed from the other side along the third direction DR3.

The display device according to some other embodiments of FIGS. 10 and 11 differs from the embodiments of FIGS. 1 to 7 only in the arrangement of the coating layer 100. Accordingly, in FIGS. 10 and 11, descriptions overlapping with the embodiments of FIGS. 1 to 7 may not be repeated.

In FIGS. 10 and 11, the first area A1 is shown as having a similar size to the main area MA. However, this is merely an example, and the first area A1 is where the coating layer 100 in the main area MA is placed, and may be smaller or larger than the main area MA depending on the purpose and use of the display device 1. Also, in FIGS. 10 and 11, the first area A1 is shown as being singular, but this is only an example, and the first area A1 is an area where the coating layer 100 is placed in the main area MA, and depending on the purpose and use of the display device 1, it can be provided in singular or plural form at any position in the main area MA on the back of the display panel PNL.

In FIG. 10 and FIG. 11, the second area A2 is shown as having a similar size to the sub-area SBA, but this is merely an example, and the second area A2 is the coating layer 100 where the sub-area SBA is placed, and may be smaller or larger than the sub-area SBA depending on the purpose and use of the display device 1. In addition, in FIGS. 10 and 11, the second area A2 is shown in singular form, but this is merely an example. The second area A2 is an area in the sub-area SBA where the coating layer 100 is disposed, and depending on the purpose and use of the device 1, it may be provided in singular or plural form at any location within the sub-area SBA on the back of the display panel PNL.

The coating layer 100 may be the light blocking cushion portion 101 and a second support portion 105 disposed on the light blocking cushion portion 101. The light blocking cushion portion 101 and a second support portion 105 may be disposed in the first area A1. The light blocking cushion portion 101 and a second support portion 105 may be disposed in the second area A2. The second support portion 105 may be arranged to support the display panel PNL. The light blocking cushion portion 101 and the second support portion 105 may include different materials.

In a plane perpendicular to the third direction DR3, the second support portion 105 may have a round shape at one corner area. The second support portion 105 may have a shape whose thickness gradually decreases from one end to the outside. In a cross-section perpendicular to one surface of the display panel PNL, the second support portion 105 may have a shape whose thickness along the third direction DR3 gradually decreases as it moves outward along the second direction DR2.

In some embodiments, the second support portion 105 may include a second material including at least one of silicon, urethane, epoxy acrylate, or polyethylene. For example, the second support portion 105 may be formed by curing ink containing the second material, but is not limited thereto. The second support portion 105 may include the same or substantially the same material as the first support portion 103, but is not limited thereto.

In the display device according to some other embodiments described above, the light blocking cushion portion and the second support portion can be laminated through an inkjet printing process, so that the structure that protects the display panel can be manufactured more simply and efficiently.

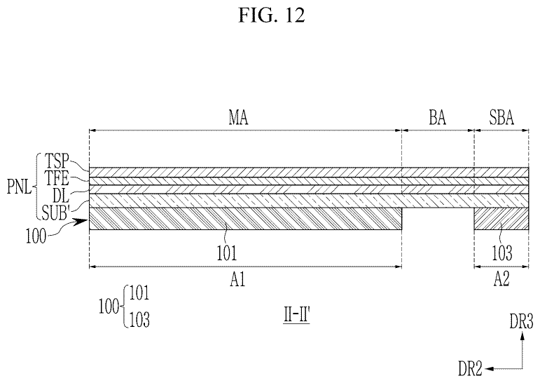

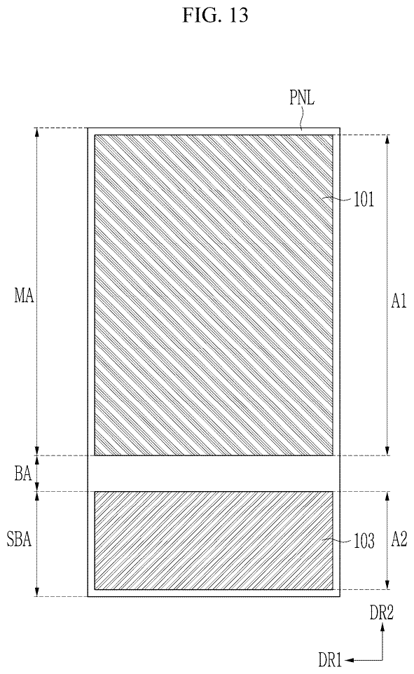

FIG. 12 is a cross-sectional view of a display device taken along the line II-II′ of FIG. 1, according to some other embodiments of the present disclosure; and FIG. 13 is a top view of the display device according to some other embodiments of the present disclosure. FIG. 13 is a plan view showing the rear of the display device 1 viewed from the other side along the third direction DR3.

The display device according to some other embodiments of FIGS. 12 and 13 differs from the embodiments of FIGS. 1 to 7 only in the shape and configuration of 1 the substrate SUB′. Therefore, in FIGS. 12 and 13, descriptions overlapping with the embodiments of FIGS. 1 to 7 may not be repeated.

Referring to FIGS. 12 and 13, the substrate SUB′ of a display device according to some other embodiments may be a flexible substrate including a flexible polymer material such as polyimide. The substrate SUB′ may be exposed on one side of the display panel PNL. Accordingly, the display panel PNL may be partially bent, curved, bent, folded, or rolled to fit various platforms (e.g., may be rollable, slidable, foldable platforms, etc.) of the display device 1. It can be formed flexibly.

The substrate SUB′ may extend along the second direction DR2. The

substrate SUB′ may have a main area MA, a bending area BA, and a sub-area SBA. The substrate SUB′ may overlap the light blocking cushion portion 101 and the first support portion 103.

In the display device according to some other embodiments described above, by forming a coating layer that functions for light blocking, impact-resistance, and supporting through inkjet printing, the above-mentioned problems are prevented or substantially mitigated, material costs are reduced, and desired characteristics for each position of the display panel are maintained. Additionally, by forming a coating layer directly on the bottom of the substrate, it can also have an additional heat dissipation function.

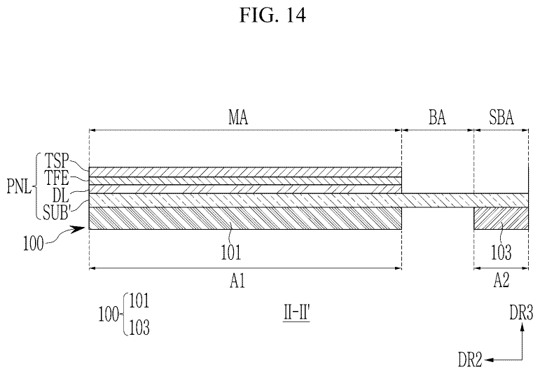

FIG. 14 is a cross-sectional view of a display device according to a modified example.

Referring to FIG. 14 together with FIG. 12, the display device according to the modified example is the display device according to some other embodiments described with reference to FIGS. 12 and 13, except that the electrode layer TSP is located in the main area MA. In other words, the display layer DL, the thin film encapsulation layer TFE, and the touch electrode layer TSP may not exist or be located in the bending area BA and the sub-area SBA. Therefore, in FIG. 14, descriptions overlapping with the embodiments of FIGS. 1 to 7 may not be repeated.

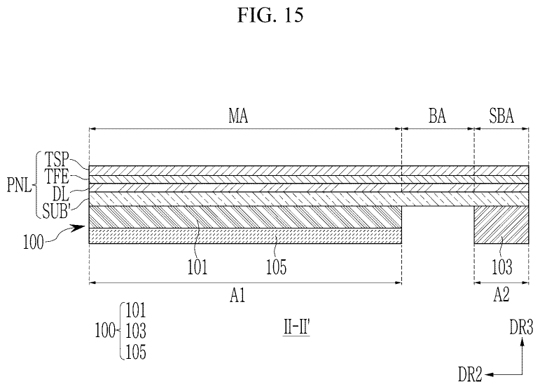

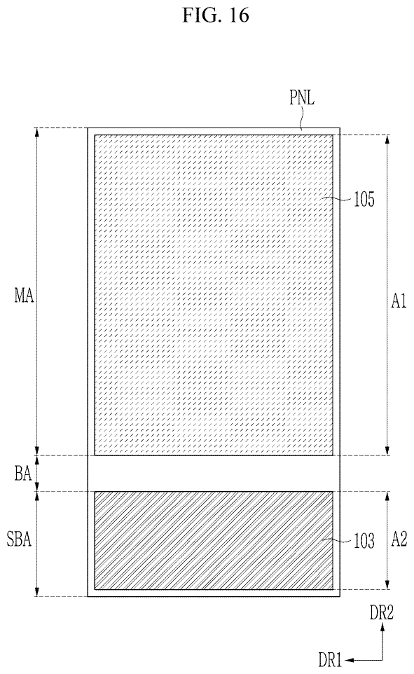

FIG. 15 is a cross-sectional view of a display device taken along the line II-II′ of FIG. 1, according to some other embodiments of the present disclosure; and FIG. 16 is a top view of the display device according to some other embodiments of the present disclosure. FIG. 16 is a plan view showing the rear of the display device 1 viewed from the other side along the third direction DR3.

The display device according to some other embodiments of FIGS. 15 and 16 differs from the some other embodiments of FIGS. 12 and 13 only in the shape and configuration of the coating layer 100. Therefore, in FIGS. 15 and 16, descriptions overlapping with the embodiments of FIGS. 12 and 13 may not be repeated.

Referring to FIGS. 15 and 16, the coating layer 100 may include the light blocking cushion portion 101, a first support portion 103, and a second support portion 105. The light blocking cushion portion 101 may be disposed in the first area A1. The first support portion 103 may be disposed in the second area A2. The second support portion 105 may be disposed in at least a portion of the first area A1. The second support portion 105 may be disposed on the light blocking cushion portion 101. The second support portion 105 may be arranged to support the display panel PNL. The light blocking cushion portion 101 and the first and second support portions 103 and 105 may include different materials.

The light blocking cushion portion 101 according to some other embodiments may have a different thickness from the first support portion 103. In terms of thickness along the third direction DR3, the thickness of the light blocking cushion portion 101 and the first support portion 103 may be different. The thickness of the first support portion 103 may be greater than the thickness of the light blocking cushion portion 101.

In a plane perpendicular to the third direction DR3, the second support portion 105 may have a round shape at one corner area. The second support portion 105 may have a shape whose thickness gradually decreases from one end to the outside. In a cross-section perpendicular to one surface of the display panel PNL, the second support portion 105 may have a shape whose thickness along the third direction DR3 gradually decreases as it moves outward along the second direction DR2.

In some embodiments, the second support portion 105 may include a second material including at least one of silicon, urethane, epoxy acrylate, and polyethylene. For example, the second support portion 105 may be formed by curing ink containing the second material, but is not limited thereto. The second support portion 105 may include the same or substantially the same material as the first support portion 103, but is not limited thereto.

In the display device according to some other embodiments described above, the light blocking cushion portion 101, the first support portion 103, or the second support portion 105 can be formed at a desired location with a desired shape and thickness depending on the level of desired functional characteristics such as shock resistance, light blocking, and support, and the desired characteristics for each location of the display panel can be efficiently secured.

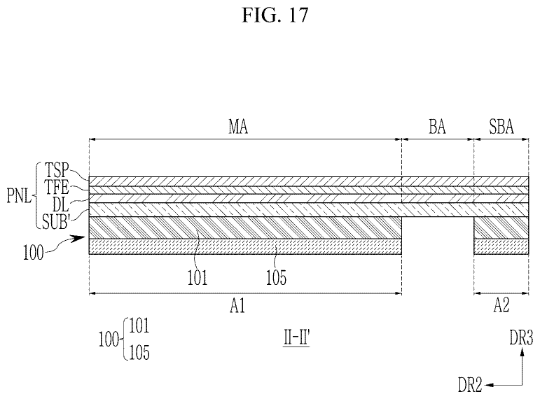

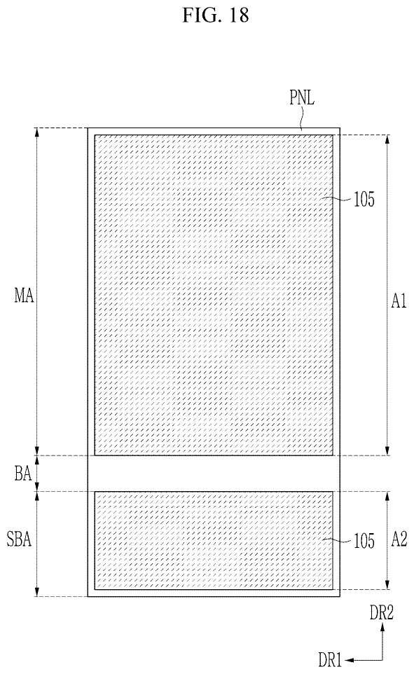

FIG. 17 is a cross-sectional view of a display device taken along the line II-II′ of FIG. 1, according to some other embodiments of the present disclosure; and FIG. 18 is a top view of the display device according to some other embodiments of the present disclosure. FIG. 18 is a plan view showing the rear of the display device 1 viewed from the other side along the third direction DR3.

The display device according to some other embodiments of FIGS. 17 and 18 differs from the some other embodiments of FIGS. 12 and 13 only in the arrangement of the coating layer 100. Therefore, in FIGS. 17 and 18, descriptions overlapping with the embodiments of FIGS. 12 and 13 may not be repeated.

In FIGS. 17 and 18, the first area A1 is shown to have a similar size to the main area MA. However, this is merely an example, and the first area A1 is where the coating layer 100 in the main area MA is placed, and may be smaller or larger than the main area MA depending on the purpose and use of the display device 1. In addition, in FIGS. 17 and 18, the first area A1 is shown in singular form, but this is merely an example. The first area A1 is an area in the main area MA where the coating layer 100 is disposed, and is particularly defined depending on the purpose and use of the device 1, and one or more devices may be provided at any location within the main area MA on the back of the display panel PNL.

In FIGS. 17 and 18, the second area A2 is shown to have a similar size to the sub-area SBA, however, this is an merely example, and the second area A2 is where the coating layer 100 in the sub-area SBA is placed, and may be smaller or larger than the sub-area SBA depending on the purpose and use of the display device 1. In addition, in FIGS. 10 and 11, the second area A2 is shown in singular form, but this is merely an example, and the second area A2 is an area in the sub-area SBA where the coating layer 100 is disposed, and is particularly defined depending on the purpose and use of the device 1, and it may be provided in singular or plural form at any location within the sub-area SBA on the back of the display panel PNL.

The coating layer 100 may include the light blocking cushion portion 101 and a second support portion 105 disposed on the light blocking cushion portion 101. The light blocking cushion portion 101 and a second support portion 105 may be disposed in the first area A1. The second support portion 105 may be arranged to support the display panel PNL. The light blocking cushion portion 101 and a second support portion 105 may be disposed in the second area A2. The light blocking cushion portion 101 and the second support portion 105 may include different materials. In a plane perpendicular to the third direction DR3, the second support portion 105 may have a round shape at one corner area. The second support portion 105 may have a shape whose thickness gradually decreases from one end to the outside. In a cross-section perpendicular to one side of the display panel PNL, the second support portion 105 may have a shape whose thickness along the third direction DR3 gradually decreases as it moves outward along the second direction DR2.

In some embodiments, the second support portion 105 may include a second material including at least one of silicon, urethane, epoxy acrylate, and polyethylene. For example, the second support portion 105 may be formed by curing ink containing the second material, but is not limited thereto. The second support portion 105 may include the same or substantially the same material as the first support portion 103, but is not limited thereto.

In the display device according to some other embodiments described above, the light blocking cushion portion and the second support portion can be laminated through an inkjet printing process, so that the structure that protects the display panel can be manufactured more simply and efficiently.

Hereinafter, a method of manufacturing a display device according to some embodiments will be described.

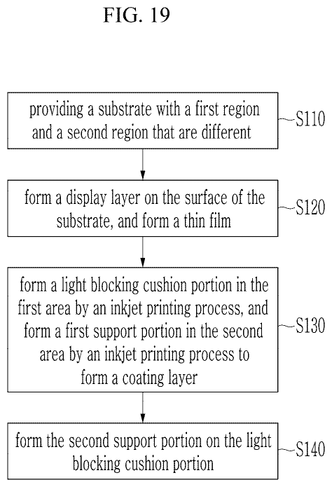

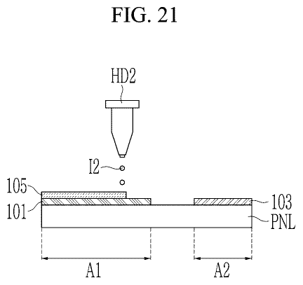

FIG. 19 is a flowchart showing a method of manufacturing a display device according to some embodiments of the present disclosure; FIG. 20 is a top view showing process S130 of FIG. 19, according to some embodiments of the present disclosure; and FIG. 21 is a top view showing process S140 of FIG. 19, according to some embodiments of the present disclosure.

Referring to FIG. 19, in a method of manufacturing a display device according to some embodiments, a substrate SUB′ having different first areas A1 and second areas A2 on one surface is provided (S110).

Additionally, a display layer DL is formed on the other side of the substrate SUB′, and a thin film encapsulation layer TFE is formed on the display layer DL S120.

Then, the light blocking cushion portion 101 is formed in the first area A1 of the substrate SUB′ by an inkjet printing process, and the first light blocking cushion portion 101 is formed in the second area A2 of the substrate SUB′ by an inkjet printing process. The support portion 103 is formed to form the coating layer 100 (S130). In other words, the coating layer 100 including the light blocking cushion portion 101 and the first support portion 103 can be formed on one surface of the substrate SUB′ through an inkjet printing process.

The coating layer 100 may be formed by an inkjet head applying Ink to the display panel PNL and curing the ink. However, it is not limited to this, and the coating layer 100 may be formed by a coating process such as screen printing or with a dispenser. The coating layer 100 may be cured through at least one of ultraviolet curing, thermal curing, and natural curing.

As described above with reference to FIG. 5, the light blocking cushion portion 101 may be formed to have a different thickness from the first support portion 103. Additionally, the light blocking cushion portion 101 and the first support portion 103 may be formed of different materials.

For example, referring to FIG. 20, the light blocking cushion portion 101 is configured such that the first inkjet head HD1 applies the first ink 11 containing the first material to the first area A1, and it can be formed by curing the first ink 11. So that the light blocking cushion portion 101 can perform both light blocking and impact resistance functions, the first material may be a mixture of an elastic material including at least one of silicon, urethane, epoxy acrylate, and polyethylene, and a light blocking material containing at least one of GO (graphene oxide), RGO (reduced graphene oxide), aluminum, CB (carbon black), and copper Cu.

In addition, referring to FIG. 20, the first support portion 103 may be formed by the second inkjet head HD2 applying the second ink 12 comprising the second material to the second region A2 and curing the applied second ink 12. So that the first support portion 103 can perform the support and protection function, the second material may include at least one of silicon, urethane, epoxy acrylate, and polyethylene. The second material may be a high modulus material. The second material may be a low viscosity material of 30 cPs or less. The first support portion 103 can protect the display device 1 from external foreign substances and prevent scratches from occurring.

Additionally, a second support portion 105 is formed on the light blocking cushion portion 101 (S140). However, this is optional, and the coating layer 100 may include only the light blocking cushion portion 101 and the first support portion 103 located on one surface of the substrate SUB′.

For example, referring to FIG. 21, the second support portion 105 applies the second ink 12 containing the second material to the light blocking cushion portion 101 by the second inkjet head HD2, and it can be formed by curing the applied second ink 12. However, it is not limited thereto, and the second support portion 105 may include a different material from the first support portion 103. So that the second support portion 105 can perform the support and protection functions, the second material may include at least one of silicon, urethane, epoxy acrylate, and polyethylene. The second material may be a high modulus material. The second material may be a low viscosity material of 30 cPs or less. The second support portion 105 can protect the display device 1 from external foreign substances and prevent or substantially reduce scratches from occurring.

The multilayer structure of the coating layer 100 can be implemented using methods such as arranging inkjet heads, changing the nozzle size, or reciprocating coating.

In the manufacturing method of the display device according to the above-described embodiment, the material cost can be reduced and the tolerance can be reduced by coating and forming a light blocking and impact-resistant layer and a support function layer through inkjet printing, so it is possible to secure the desired characteristics for each location of the display panel. In addition, the thickness, size, shape, etc. of the light blocking and impact-resistant layer and the support layer can be easily controlled.

Hereinafter, a method of manufacturing a display device according to some other embodiments will be described.

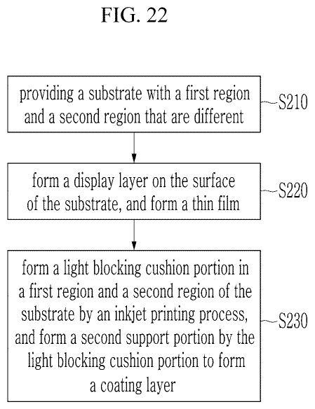

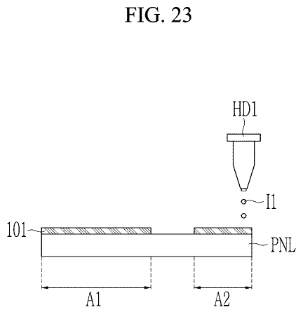

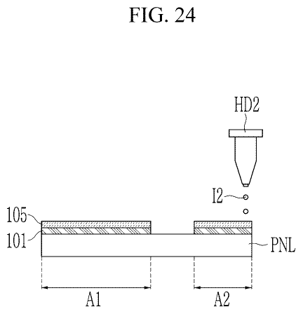

FIG. 22 is a flowchart showing a method of manufacturing a display device according to some other embodiments of the present disclosure; and FIGS. 23 and 24 are plan views showing the process S230 of FIG. 22, according to some other embodiments of the present disclosure.

Referring to FIG. 22, in a method of manufacturing a display device according to some other embodiments, a substrate SUB′ having different first areas A1 and second areas A2 on one surface is provided (S210).

Additionally, a display layer DL is formed on the other side of the substrate SUB′, and a thin film encapsulation layer TFE is formed on the display layer DL (S220).

Then, the light blocking cushion portion 101 is formed in the first area A1 and the second area A2 of the substrate SUB′ by an inkjet printing process, and the light blocking cushion portion 101 is formed on the light blocking cushion portion 101 by an inkjet printing process, while a coating layer is formed by forming the second support portion 105 (S230). In other words, the coating layer 100 including the light blocking cushion portion 101 and the first support portion 103 can be formed on one surface of the substrate SUB′ through an inkjet printing process.

The coating layer 100 may be formed by an inkjet head applying Ink to the display panel PNL and curing the ink. However, it is not limited to this, and the coating layer 100 may be formed by a coating process such as screen printing or by using a dispenser. The coating layer 100 may be cured through at least one of ultraviolet curing, thermal curing, and natural curing.

The light blocking cushion portion 101 may be formed to have a different thickness from the second support portion 105. Additionally, the light blocking cushion portion 101 and the second support portion 105 may be formed of different materials.

For example, referring to FIG. 23, the light blocking cushion portion 101 may be formed by a first inkjet head HD1 applying a first ink 11 comprising a first material to the first region A1 and the second region A2, and curing the applied first ink 11. So that the light blocking cushion portion 101 can perform both light blocking and impact resistance functions, the first material may be a mixture of an elastic material including at least one of silicon, urethane, epoxy acrylate, and polyethylene, and a light-blocking material containing at least one of graphene oxide (GO), reduced graphene oxide (RGO), aluminum, carbon black (CB), and copper (Cu).

Additionally, a second support portion 105 is formed on the light blocking cushion portion 101. For example, referring to FIG. 24, the second support portion 105 applies the second ink 12 containing the second material to the light blocking cushion portion 101 by the second inkjet head HD2, and it can be formed by curing the applied second ink 12. However, it is not limited thereto, and the second support portion 105 may include a different material from the first support portion 103. So that the second support portion 105 can perform the support and protection function, the second material may include at least one of silicon, urethane, epoxy acrylate, and polyethylene. The second material may be a high modulus material. The second material may be a low viscosity material of 30 cPs or less. The second support portion 105 can protect the display device 1 from external foreign substances and prevent scratches from occurring.

The multilayer structure of the coating layer 100 can be implemented using methods such as arranging inkjet heads, changing nozzle sizes, or reciprocating coating.

According to the method of manufacturing a display device according to some other embodiments described above, a layer having a light blocking and impact-resistant function and a layer having a supporting function are coated and formed through inkjet printing, thereby reducing material costs and reducing tolerances, it is possible to secure the required characteristics for each location of the display panel. In addition, the thickness, size, and shape of the light blocking and impact-resistant layers and the support layer can be easily controlled, and the light blocking cushion portion and the second support portion can be stacked and formed through the inkjet printing process, making it possible to manufacture a structure that protects the display panel more simply and efficiently.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

### DESCRIPTION OF SOME OF THE REFERENCE NUMERALS

1: display device
PNL: display panel
TH: through portion
SUB, SUB′: substrate
DL: display layer
TFE: thin film encapsulation layer
TSP: touch electrode layer
100: coating layer
101: light blocking cushion portion
103: first support portion
105: second support portion
HD1, HD2: first and second inkjet head
FA: flat portion
SA: slope portion

What is claimed is:

1. A display device comprising:
a display panel having different first and second areas on one surface; and
a coating layer on the one surface of the display panel, the coating layer comprising a light blocking cushion portion in the first area, and a first support portion in the second area located on one side of the first area to support the display panel.

2. The display device of claim 1, wherein the light blocking cushion portion has a different thickness from the first support portion.

3. The display device of claim 1, wherein the coating layer further comprises a second support portion on the light blocking cushion portion.

4. The display device of claim 1, wherein the coating layer has a shape where the thickness gradually decreases from one end to the outside.

5. The display device of claim 1, wherein in a plane parallel to the one surface of the display panel, the coating layer has a round shape at one corner area.

6. The display device of claim 1, wherein the light blocking cushion portion comprises a first material mixed with an elastic material that comprises at least one of silicon, urethane, epoxy acrylate, or polyethylene, and a light blocking material comprising at least one of graphene oxide (GO), reduced graphene oxide (RGO), aluminum, carbon black (CB), or copper (Cu).

7. The display device of claim 1, wherein the first support portion comprises a second material comprising at least one of silicon, urethane, epoxy acrylate, or polyethylene.

8. The display device of claim 1, wherein the display panel comprises a bending area adjacent to the first area on the one surface.

9. The display device of claim 8, wherein the first area is located on one side of the bending area in a first direction, and the second area is located on an other side of the bending area in the first direction.

10. The display device of claim 8, wherein the display panel comprises a substrate exposed on the one surface and comprising glass.

11. The display device of claim 10, wherein the substrate comprises:
a through portion in which the bending area is etched,
a first substrate on one side of the through portion in a first direction, and
a second substrate located on an other side of the through portion in the first direction.

12. The display device of claim 8, wherein the display panel comprises a substrate exposed on the one surface and comprising polyimide.

13. A display device comprising:
a display panel; and
a coating layer on one side of the display panel, the coating layer comprising a light blocking cushion portion on the one side of the display panel, and a support portion on the light blocking cushion portion to support the display panel.

14. The display device of claim 13, wherein the light blocking cushion portion comprises a first material mixed with an elastic material that comprises at least one of silicon, urethane, epoxy acrylate, or polyethylene, and a light blocking material comprising at least one of graphene oxide (GO), reduced graphene oxide (RGO), aluminum, carbon black (CB), or copper (Cu).

15. The display device of claim 13, wherein the support portion comprises a second material comprising at least one of silicon, urethane, epoxy acrylate, or polyethylene.

16. A method of manufacturing a display device, the method comprising:
providing a substrate having different first and second regions on one surface;
forming a light emitting layer on an other side of the substrate and forming a thin film encapsulation layer on the light emitting layer;
forming a light blocking cushion in a first area of the substrate through an inkjet printing process, and forming a first support portion in a second area of the substrate through the inkjet printing process to form a coating layer.

17. The method of manufacturing a display device of claim 16, wherein the forming of the light blocking cushion portion comprises:
the forming of the light blocking cushion portion to have a different thickness from the first support portion.

18. The method of manufacturing a display device of claim 16, wherein the forming of the coating layer further comprises:
forming of a second support portion on the light blocking cushion portion.

19. The method of manufacturing a display device of claim 16, wherein the forming the coating layer comprises:
forming the light blocking cushion portion using a first material mixed with an elastic material comprising at least one of silicon, urethane, epoxy acrylate, or polyethylene, and a light blocking material comprising at least one of graphene oxide (GO), reduced graphene oxide (RGO), aluminum, forming carbon black (CB), or copper (Cu); and
forming of the first support portion using a second material comprising at least one of silicon, urethane, epoxy acrylate, or polyethylene.

20. A method of manufacturing a display device, the method comprising:
providing a substrate having different first and second regions on one surface;
forming a light emitting layer on an other side of the substrate and forming a thin film encapsulation layer on the light emitting layer;
forming a light blocking cushion portion in the first region and the second region of the substrate by an inkjet printing process; and
forming a support portion on the light blocking cushion portion by the inkjet printing process to comprise a different material from the light blocking cushion portion to form a coating layer.
